(19) United States
(12) Patent Application Publication
(10) Pub. No.: US 2012/0133609 A1
(43) Pub. Date: May 31, 2012

(54) RESISTIVE TYPE TOUCH PANEL AND METHOD OF MANUFACTURING THE SAME

(75) Inventors: Woon Chun Kim, Gyunggi-do (KR); Jae Il Kim, Gyunggi-do (KR); Yong Soo Oh, Gyunggi-do (KR); Jong Young Lee, Gyunggi-do (KR)

(73) Assignee: SAMSUNG ELECTRO-MECHANICS CO., LTD., Gyunggi-do (KR)

(21) Appl. No.: 13/043,663

(22) Filed: Mar. 9, 2011

(30) Foreign Application Priority Data
Nov. 29, 2010 (KR) 1020100119733

(51) Int. Cl. G06F 3/045; H05K 13/00

(52) U.S. Cl. 345/174; 29/592.1

(57) ABSTRACT

Disclosed herein is a resistive type touch panel according to a preferred embodiment of the present invention. The resistive type touch panel includes a transparent substrate; a transparent electrode formed on one surface of the transparent substrate and made of a conductive polymer; and a plurality of conductive balls formed on the transparent electrode and having conductivity. According to the present invention, the conductive balls are included in the transparent electrode made of the conductive polymer to improve the conductivity of the transparent electrode and the conductive balls are formed on the transparent electrode at a predetermined interval, thereby making it possible to constantly maintain the thickness of the transparent electrode. Further, the conductive balls are formed on the transparent electrode to reduce the contact resistance value generated when the resistive type touch panel is touched, thereby making it possible to improve the reliability of the operation of the touch panel.

### CROSS REFERENCE TO RELATED APPLICATION

This application claims the benefit of Korean Patent Application No. 10-2010-0119733, filed on Nov. 29, 2010, entitled “Resistive Type Touch Panel and Method of Manufacturing The Same” which is hereby incorporated by reference in its entirety into this application.

### BACKGROUND OF THE INVENTION

1. Technical Field

The present invention relates to a resistive type touch panel and a method of manufacturing the same.

2. Description of the Related Art

Alongside the growth of computers using digital technology, devices assisting the computers have also been developed, and personal computers, portable transmitters and other personal information processors execute processing of text and graphics using a variety of input devices such as a keyboard, a mouse and so on. While the rapid advancement of the information-based society has been widening the use of computers more and more, there have been occurring the problems of it being difficult to efficiently operate products using only the keyboard and mouse as being currently responsible for the input device function. Thus, the demand for a device that is simple, has minimum malfunction, and has the capability to easily input information is increasing.

Furthermore, current techniques for input devices exceed the level of fulfilling general functions and thus are progressing towards techniques related to high reliability, durability, innovation, designing and manufacturing. To this end, a touch screen has been developed as an input device capable of inputting information such as text and graphics.

The touch screen is mounted on the display surface of an image display device such as an electronic organizer, a flat panel display including a liquid crystal display (LCD), a plasma display panel (PDP), an electroluminescence (El) element or the like, or a cathode ray tube (CRT), so that a user selects the information desired while viewing the image display device.

The type of the touch screen can be classified into a resistive type, a capacitive type, an electromagnetic type, a surface acoustic wave (SAW) type, and an infrared type. Various types of touch screens are adapted for an electronic product in consideration of not only signal amplification problems, resolution differences and the degree of difficulty of designing and manufacturing technology but also in light of optical properties, electrical properties, mechanical properties, resistance to the environment, input properties, durability and economic benefits of the touch panel. In particular, resistive and capacitive types are prevalently used.

In particular, when the transparent electrode of the resistive type touch panel is made of a conductive polymer, there are problems of improving the conductivity of the conductive polymer and reducing the contact resistance value generated at the time of pressurization for touch the resistive type touch panel. Further, there is a problem in that the coating thickness of the transparent electrode formed on the transparent substrate is non-uniform at all times.

### SUMMARY OF THE INVENTION

The present invention has been made in an effort to provide a resistive type touch panel capable of improving conductivity by including conductive balls in a transparent electrode configuring the resistive type touch panel and reducing contact resistance generated when the touch panel is touched.

According to a preferred embodiment of the present invention, there is provided a resistive type touch panel, including: a transparent substrate; a transparent electrode formed on one surface of the transparent substrate and made of a conductive polymer; conductive balls formed on the transparent electrode.

The conductive polymer may include poly-3,4-ethylenedioxythiophene/polystyrenesulfonate (PEDOT/PSS), polyaniline, polyacetylene, or polyphenylenevinylene.

The conductive ball may be protrudedly formed on the transparent electrode, in a circular shape having a diameter larger than a stacked height of the transparent electrode.

The conductive ball is made of nickel (Ni) and gold (Au) to sequentially surround the outside of the polymer core, based on a polymer core.

The plurality of conductive balls may each be formed at a corresponding interval.

According to a preferred embodiment of the present invention, there is provided a method of manufacturing a resistive type touch panel, including: preparing a jig in which a plurality of vacuum suction tubes are formed; adsorbing a plurality of conductive balls in the vacuum suction tubes; seating the plurality of conductive balls adsorbed in the vacuum suction tubes on the transparent substrate by heating and pressurizing the conductive balls; and applying a conductive polymer on a transparent substrate in which the conductive balls are seated.

The conductive polymer may include poly-3,4-ethylenedioxythiophene/polystyrenesulfonate (PEDOT/PSS), polyaniline, polyacetylene, or polyphenylenevinylene.

The conductive ball may be protrudedly formed on the transparent electrode, in a circular shape having a diameter larger than a stacked height of the transparent electrode.

The conductive ball is made of nickel (Ni) and gold (Au) to sequentially surround the outside of the polymer core, based on a polymer core.

The plurality of conductive balls may each be formed at a corresponding interval.

### BRIEF DESCRIPTION OF THE DRAWINGS

FIG. 1 is a cross-sectional view of a transparent substrate and a transparent electrode included in a resistive type touch panel according to the present invention; and

FIGS. 2 to 7 are diagrams showing a method of manufacturing a resistive type touch panel according to the present invention.

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted.

Hereinafter, preferred embodiments of the present invention will be described in detail with reference to the accompanying drawings.

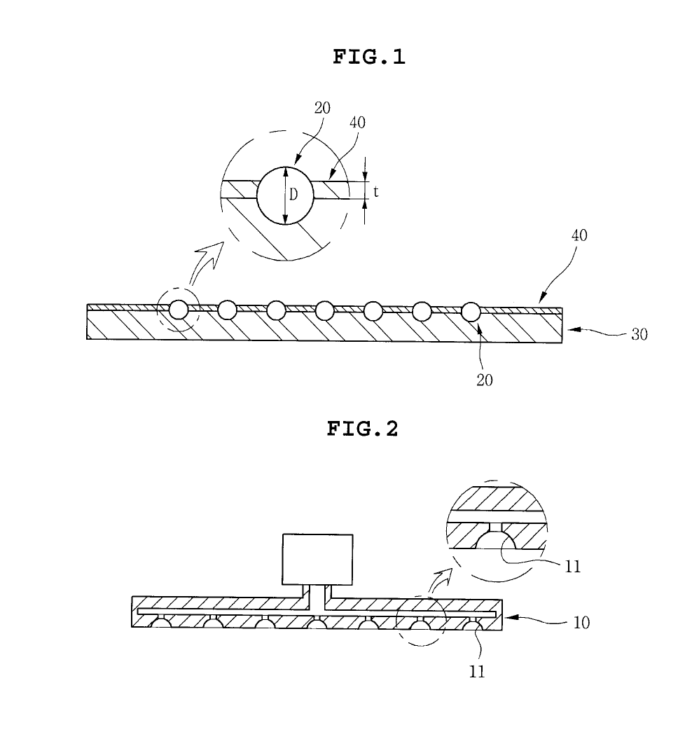

FIG. 1 is a cross-sectional view of a transparent substrate 30 and a transparent electrode 40 included in a resistive type touch panel according to the present invention. The resistive type touch panel according to a preferred embodiment of the present invention is configured to include the transparent substrate 30, the transparent electrode 40 formed on one surface of the transparent substrate 30 and made of a conductive polymer, and conductive balls 20 formed on the transparent electrode 40.

A material of the transparent substrate 30 is not particularly limited if it has a predetermined strength or more. An example of the material of the transparent substrate 30 may include polyethyleneterephthalate (PET), polycarbonate (PC), polymethylmethacrylate (PMMA), polyethylenenaphthalate (PEN), polyethersulfone (PES), cyclic olefin polymer (COC), triacetylcellulose (TAC) film, polyvinyl alcohol (PVA) film, polyimide (PI) film, polystyrene (PS), biaxially oriented polystyrene (BOPS; containing K resin), glass or reinforced glass, and so on. Further, since the transparent electrode 40 is formed on one surface of the transparent substrate 30, a surface treatment layer may be formed by performing a high frequency treatment, a primer treatment, or the like, on one surface of the transparent substrate 30 in order to improve an adhesion between the transparent substrate 30 and the transparent electrode 40.

The transparent electrode 40 serves to generate signals when a touch panel is touched by a user to allow a controller (not shown) to recognize coordinates thereof. The transparent electrode is formed on one surface of the transparent substrate 30. In this case, the transparent electrode 40 is made of a conductive polymer. An example of the conductive polymer may include poly-3,4-ethylenedioxythiophene/polystyrenesulfonate (PEDOT/PSS), polyaniline, polyacetylene, polyphenylenevinylene, or the like, but is not particularly limited thereto. The transparent electrode 40 is provided with the plurality of conductive balls 20 having conductivity. The conductive ball 20 is formed on the transparent electrode 40 to improve the conductivity of the transparent electrode 40, thereby making it possible to reduce the contact resistance when the resistive type touch panel is operated. The conductive balls 20 are formed on the transparent electrode 40 at a predetermined interval. In this case, the width of the interval is not particularly defined. However, it is preferable that at least one conductive ball 20 is protrudedly formed on the transparent electrode 40 in order to contact an area in which the contact resistance is generated when the touch panel is touched.

All of the plurality of conductive balls 20 are included in the transparent electrode and are formed to have a uniform diameter, thereby making it possible to appropriately supply the formation height of the transparent electrode 40. In addition, it is possible to appropriately maintain the stacked height of the transparent electrode 40 even in the case where a pressure is repeatedly applied when the resistive type touch screen is operated As shown in FIG. 1, a diameter D of the conductive ball 20 may be formed to be larger than a stacked height t of the transparent electrode 40. That is, the conductive ball 20 is formed to be protruded on the transparent electrode 40, thereby reducing the contact resistance generated when the touch screen is pressurized and improve the reliability of the operation of the touch screen. The shape of the conductive ball 20 is not necessarily limited thereto. Therefore, the diameter D of the conductive ball 20 and the stacked height t of the transparent electrode 40 may be appropriately controlled to correspond to the formation height of the transparent electrode 40. The conductive ball 20 is generally made of nickel and gold to sequentially surround the outside of the polymer core, based on a polymer core. The conductive ball 20 is made of nickel and gold to surround the polymer core, thereby increasing conductivity. The conductive balls 20 having good conductivity are uniformly distributed on the transparent electrode 40, thereby making it possible to improve the conductivity of the entire transparent electrode 40 and reduce the contact resistance at a contact portion when the resistive type touch panel is operated.

The conductive ball 20 may be made of carbon fiber, metal (Ni, solder), or (Ni, Au)-coated polymer, or the like. Among others, the conductive ball 20 made of a metal-coated polymer may be used. The structure of the conductive ball 20 may be made of the metal-coated polymer. The conductive ball generated by sequentially coating nickel and gold on the polymer spacer core has been prevalently used. It is preferable that the conductive ball 20 is transparent. However, the conductive ball 20 may have opaque characteristics due to the coating of the conductive metal. However, although the conductive ball 20 is not completely transparent, the size and density of the conductive ball 20 existing on the transparent electrode 40 are not too high and as a result, the entire transmittance has not been influenced greatly.

FIGS. 2 to 7 are diagrams showing a method of manufacturing a resistive type touch panel according to the present invention. A method of manufacturing a resistive type touch panel according to a preferred embodiment of the present invention includes preparing a jig 10 in which a plurality of vacuum suction tubes 11, adsorbing a plurality of conductive balls 20 in the vacuum suction tubes 1, seating the conductive balls 20 adsorbed in the vacuum suction tubes 11 on the transparent substrate 30 by heating and pressurizing the conductive balls 20, and applying a conductive polymer to the transparent substrate 30 on which the conductive ball 20 is seated.

Hereinafter, the repeated content with the description of the resistive type touch panel will be omitted.

FIG. 2 is a diagram showing a process of preparing the jig 10 in which the plurality of vacuum suction tubes 11 are formed. The vacuum suction tubes 11 are formed to suck the plurality of conductive balls 20, respectively, which will be seated on the transparent substrate 30. The plurality of conductive balls 20 are formed on the transparent electrode 40, such that the vacuum suction tubes 11 may be formed in the corresponding interval and number. As shown in FIG. 2, the vacuum suction tube 11 may be formed to stably suck and fix the conductive balls 20 in a semicircle, but is not necessarily limited thereto. The vacuum suction tube 11 may also be designed in other shapes if the conductive ball 20 may be attached to the transparent substrate 30 by being fixed to the jig 10 by the suction force of the vacuum suction tube 11.

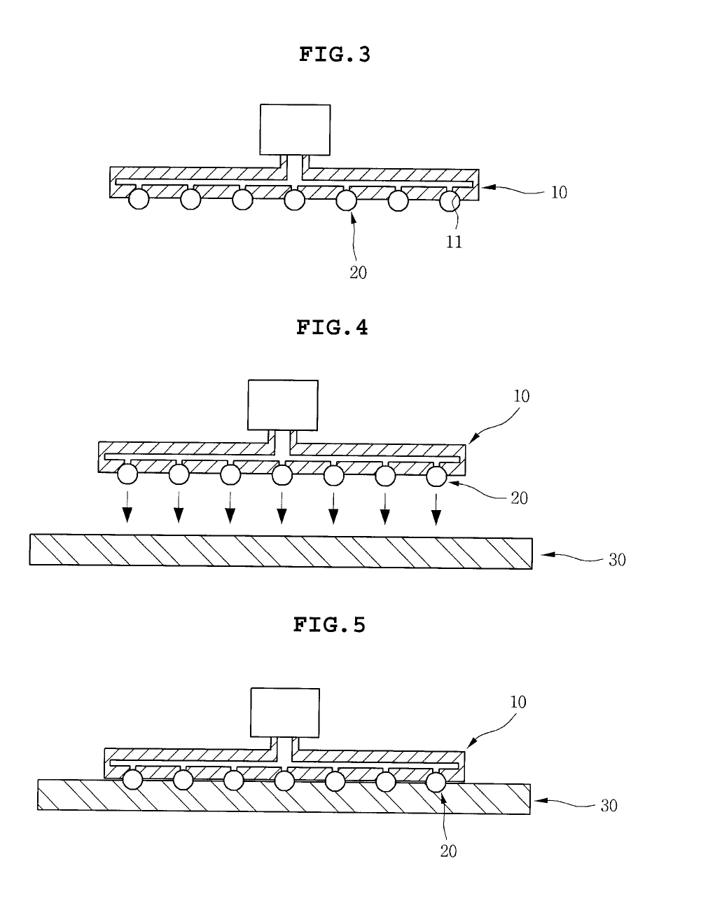

FIG. 3 is a diagram showing a process of adsorbing the plurality of conductive balls 20 in the plurality of vacuum suction tubes 11. The conductive balls 20 may each be adsorbed by the vacuum suction force and when the conductive balls 20 are attached to the transparent substrate 30, the conductive balls 20 may be separated from the vacuum suction tube 11 by reducing the vacuum suction force.

FIGS. 4 and 5 are diagrams showing a process of seating the conductive balls 20 adsorbed in the vacuum suction tube 11 on the transparent substrate 30 by heating and pressurizing the conductive balls 20. The adhesion to the transparent substrate 30 may be increased by applying heat and pressure to the conductive balls 20. The transparent electrode 40 may be coupled with the conductive ball 20 by seating the conductive ball 20 on the transparent substrate 30 at a predetermined interval and then, forming the transparent electrode 40 on the transparent substrate 30.

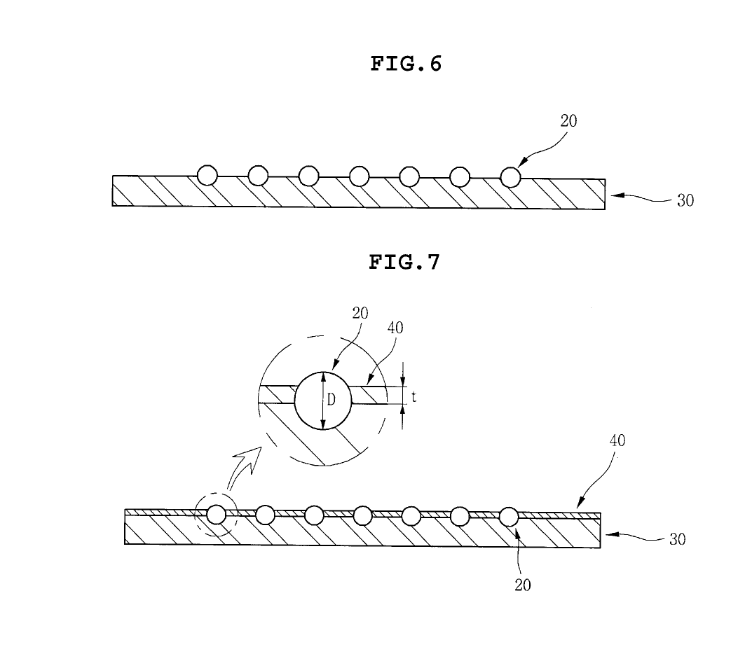

FIG. 6 is a diagram showing a state in which the conductive ball 20 is seated on the transparent substrate 30 as shown in FIGS. 4 and 5. When the transparent electrode 40 is formed, the conductive ball 20 is appropriately pressurized and heated so as not to move or detach the conductive ball 20, thereby making it possible to stably attach the conductive ball 20 to the transparent substrate 30.

FIG. 7 is a diagram showing a process of coating a conductive polymer on the transparent substrate 30 on which the conductive ball 20 is formed. The conductive polymer may be formed by a coating or printing method, but is not particularly limited thereto. Therefore, all the methods of forming the conductive polymer on the transparent substrate 30 may be used. Finally, if the transparent electrode 40 made of a conductive polymer is formed on the transparent substrate 30, the combined structure of the transparent electrode 40 and the conductive ball 20 may be implemented. The conductive ball 20 is uniformly distributed on the transparent electrode 40 made of the conductive polymer, thereby making it possible to improve the conductivity and reduce the contact resistance generated when the resistive type touch panel is touched.

As set forth above, the present invention includes the conductive balls in the transparent electrode made of the conductive polymer, thereby making it possible to improve the conductivity of the transparent electrode.

Further, the present invention forms the conductive balls in the transparent electrode at a predetermined interval, thereby making it possible to constantly maintain the thickness of the transparent electrode.

In addition, the present invention forms the conductive balls in the transparent electrode to reduce the contact resistance value generated when the resistive type touch panel is touched, thereby making it possible to improve the reliability of the operation of the touch panel.

Although the preferred embodiments of the present invention have been disclosed for illustrative purposes, they are for specifically explaining the present invention and thus a resistive type touch panel and a method of manufacturing the same according to the present invention are not limited thereto, but those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A resistive type touch panel, comprising:
a transparent substrate;
a transparent electrode formed on one surface of the transparent substrate and made of a conductive polymer; and
conductive balls formed on the transparent electrode.

2. The resistive type touch panel as set forth in claim 1, wherein the conductive polymer includes poly-3,4-ethylenedioxythiophene/polystyrenesulfonate (PEDOT/PSS), polyaniline, polyacetylene, or polyphenylenevinylene.

3. The resistive type touch panel as set forth in claim 1, wherein the conductive ball is protrudedly formed on the transparent electrode, in a circular shape having a diameter larger than a stacked height of the transparent electrode.

4. The resistive type touch panel as set forth in claim 1, wherein the conductive ball is made of nickel (Ni) and gold (Au) to sequentially surround the outside of the polymer core, based on a polymer core.

5. The resistive type touch panel as set forth in claim 1, wherein the plurality of conductive balls are each formed at a corresponding interval.

6. A method of manufacturing a resistive type touch panel, comprising:
preparing a jig in which a plurality of vacuum suction tubes are formed;
adsorbing a plurality of conductive balls in the vacuum suction tubes;
seating the plurality of conductive balls adsorbed in the vacuum suction tubes on the transparent substrate by heating and pressurizing the conductive balls; and
applying a conductive polymer on a transparent substrate in which the conductive balls are seated.

7. The method of manufacturing a resistive type touch panel as set forth in claim 6, wherein the conductive polymer includes poly-3,4-ethylenedioxythiophene/polystyrenesulfonate (PEDOT/PSS), polyaniline, polyacetylene, or polyphenylenevinylene.

8. The method of manufacturing a resistive type touch panel as set forth in claim 6, wherein the conductive ball is protrudedly formed on the transparent electrode, in a circular shape having a diameter larger than a stacked height of the transparent electrode.

9. The method of manufacturing a resistive type touch panel as set forth in claim 6, wherein the conductive ball is made of nickel (Ni) and gold (Au) to sequentially surround the outside of the polymer core, based on a polymer core.

10. The method of manufacturing a resistive type touch panel as set forth in claim 6, wherein the plurality of conductive balls are each formed at a corresponding interval.
